(19) United States
(12) Patent Application Publication
(10) Pub. No.: US 2010/0206624 A1
(43) Pub. Date: Aug. 19, 2010

(54) Electric Multilayer Component

(76) Inventor: Thomas Feichtinger, Graz (AT)

Correspondence Address: SLATER & MATSIL, L.L.P., 17950 PRESTON RD, SUITE 1000, DALLAS, TX, 75252-5793, US

(21) Appl. No.: 12/724,692

(22) Filed: Mar. 16, 2010

Related U.S. Application Data
(63) Continuation of application No. PCT/EP2008/062555, filed on Sep. 19, 2008.

(30) Foreign Application Priority Data
Sep. 19, 2007 (DE) 10 2007 044 604.9

(51) Int. Cl. H05K 1/18; H01G 4/228; H01C 7/10; H01C 7/02; H01C 7/04

(52) U.S. Cl. 174/260; 361/306.3; 338/20; 338/22 R

(57) ABSTRACT

An electric multilayer component includes a stack of dielectric layers and electrode layers arranged side by side. External contacts have different polarities that are arranged at an outer surface of the stack and are flip-chip contact-connectable. The electrode layers are connected by one end in each case to an external connection having the same polarity.

This application is a continuation of co-pending International Application No. PCT/EP2008/062555, filed Sep. 19, 2008, which designated the United States and was not published in English, and which claims priority to German Application No. 10 2007 044 604.9 filed Sep. 19, 2007, both of which applications are incorporated herein by reference.

### TECHNICAL FIELD

The invention relates generally to an electric component and, in particular embodiments, to electric multilayer components, such as a flip-chip contact-connectable electric multilayer component.

### BACKGROUND

Japanese publication JP 05-55084 discloses a multilayer capacitor having two external contacts on a side surface, said external contacts being directly connected to electrode layers.

### SUMMARY

In one aspect, an electric multilayer component is flip-chip contact-connectable with a small construction outlay.

In one embodiment, an electric multilayer component includes a stack of dielectric layers and electrode layers arranged side by side. External contacts having different polarities are arranged at one and the same outer surface of the stack. The external contacts are flip-chip contact-connectable, which means that they can be electrically connected to a printed circuit board if one side of the multilayer component is directed onto the printed circuit board. The electrode layers are connected in each case by one end to an external connection having the same polarity.

An electric multilayer component having such a construction has the advantage that it can be electrically contact-connected to a printed circuit board by means of a single outer surface, yet no plated-through holes or vias that might connect electrode layers to one another are necessary here. This is owing to the fact that the electrode layers proposed already have forms which are connected in each case by one end directly to an external connection arranged on the same side surface of the multilayer component as another external connection of opposite polarity that is directly connected to an electrode layer. A complicated construction or a complex production of a multilayer component with vias making contact with electrode layers can thus be avoided.

In accordance with one embodiment of the electric multilayer component, the stacking direction of the stack runs substantially parallel to a printed circuit board or mounting surface onto which the multilayer component can be mounted. Relative to the mounting area, therefore, the layers of the stack are arranged laterally side by side, in contrast to one above another.

Such a construction has the advantage that electrodes having comparatively simple forms can make contact directly with the external contacts of the multilayer component. A different stacking direction of the stack, for example, perpendicularly to a mounting surface, is admittedly possible, but would have the consequence that the electrodes of the multilayer component would have to be embodied in a manner not optimized with respect to space and in each case in multiply-curved fashion in order to be connected to the flip-chip contact-connectable external contacts arranged at a single outer surface of the stack.

Moreover, a mounting arrangement for a flip-chip contact-connectable electric multilayer component is specified, wherein the construction of the multilayer component corresponds to one of the embodiments described in this document and is electrically contact-connected to a printed circuit board by means of external contacts arranged at an outer surface of the multilayer component. The external contacts preferably contain silver and/or palladium. In this case, the external contacts make contact with corresponding contacts on the printed circuit board. In accordance with one embodiment of the printed circuit board, its contacts, which are contact-connectable to the multilayer component, are connected via or by means of plated-through holes to conductor tracks integrated in the printed circuit board. In accordance with one development of the mounting arrangement, the printed circuit board includes a plurality of substrate layers which are stacked one above another and between which the conductor tracks run.

In accordance with one embodiment of the electric multilayer component, the surfaces of the electrode layers overlap in orthogonal projection. Electrode layers having different polarities in interaction with a respective intervening dielectric layer can in this case produce capacitances which concomitantly determine the electrical properties of the multilayer component or of the multilayer structures in the multilayer component. Examples of multilayer structures contained in the multilayer component are multilayer varistors or multilayer capacitors.

If the stacking direction of the stack runs parallel to a mounting surface in accordance with the embodiment already mentioned then the overlap of the electrode layer surfaces in orthogonal projection likewise runs parallel to the mounting surface of the multilayer component.

One embodiment of the electric multilayer component provides for electrode layers having different polarities not to overlap in orthogonal projection, in which case they are instead arranged on a common dielectric layer and at a distance from one another. The electrode layers respectively have ends which face one another and are spaced apart from one another. As a result, comparatively small capacitances can be produced between these electrode layers, which could be advantageous for specific applications of the multilayer component, such as, for example, in microelectronics, as a multilayer capacitor or as a multilayer varistor.

Preferably, the electrode layers are shaped in such a way that they are connected to an external contact at one end in each case and run in direction-changing fashion into the interior of the stack. In this case, electrode layers having different polarities, which are adjacent, in particular, can be shaped in such a way that they firstly run substantially in opposite directions into the interior of the stack. This means that these electrode layers, as viewed from an end connected to an external contact, have a converging course that is offset laterally, i.e., parallel to the mounting board. Preferably, the electrode layers are L-shaped in this case, wherein a first limb of an L-shaped electrode layer is connected to an external contact and the second limb of the electrode layer runs substantially parallel to a mounting surface.

In the case of adjacent L-shaped electrode layers having different polarities, the respective second limbs can overlap in orthogonal projection. By way of example, capacitances can be produced in this overlap region.

In accordance with one embodiment of the electric multilayer component, the end of a second limb of an L-shaped electrode layer lies opposite the end of a second limb of an electrode layer having opposite polarity, the second limb being arranged on the same dielectric layer, wherein the ends of the two second limbs of the respective electrode layers are at a distance from one another. Consequently, comparatively small capacitances can be produced between the two L-shaped electrode layers on the same dielectric layer.

In accordance with one embodiment, the electrode layers of the multilayer component are led as far as the outer surface of the stack at a plurality of sides in each case. Where the electrode layers are led as far as the outer surface of the stack, they can also be externally contact-connected, such as, for example, if the multilayer component is embedded or buried in a printed circuit board in accordance with an embedded embodiment. By way of example, the end of a shorter limb of at least one electrode layer of the multilayer component could be led as far as a first outer surface and a longitudinal side of a longer limb of the same or of a different electrode layer could be led as far as a further outer surface of the multilayer component. The first and the further outer surface can in each case be a top or a bottom outer surface of the multilayer component. Thus, the multilayer component can advantageously be contact-connected from “above” and from “below”.

In addition or as an alternative, in the case of the multilayer component it can be provided that the further outer surface is an outer surface running perpendicularly to a printed circuit board, such that the multilayer component can be contact-connected on the one hand from “above” or from “below” and on the other hand from the “side” relative to the orientation of the multilayer component on a printed circuit board.

In accordance with one embodiment, the multilayer component is embedded in a laminate composed of printed circuit board layers and thus forms part of a mounting or electric component arrangement. In this case, the multilayer component is covered on the top side by means of a printed circuit board layer of the laminate. On the underside, a further printed circuit board layer is present, on which the multilayer component lies. In this case, individual printed circuit board layers of the laminate can have plated-through holes which, for their part, can be connected to conductor tracks printed on printed circuit board layers. The printed circuit board layers of the laminate preferably have plated-through holes which can be contact-connected to the external contacts of the multilayer component. The printed circuit board layers preferably contain a polymer.

One development of the electric multilayer component provides for a ground electrode to be arranged on a dielectric layer of the stack and to be contact-connected at one end to a ground contact arranged at an outer surface of the stack. In this case, the ground contact could be arranged on the same outer surface of the multilayer component between the external contacts that make contact with the electrode layers. A plurality of ground electrodes could be provided between dielectric layers or electrode layers respectively arranged side by side. A ground electrode can advantageously be utilized to impart a favorable filter behavior to the multilayer component, in which case it can dissipate overvoltages or associated high-frequency interference and thereby protects the multilayer component against overloading.

Preferably, the external contacts which are connected to the electrode layers are arranged as far away from one another as possible on the same outer surface of the stack. In this case, the external contacts can be arranged on different edge regions of the same outer surface of the stack. The greater the distance between the external contacts having different polarities on the same outer surface of the stack, the lower the probability becomes of a short circuit occurring between them.

In accordance with one embodiment, the outer surface of the stack is at least partly passivated. The passivation of the stack has the advantage of protecting the materials of the stack, for example, the dielectric layers, electrode layers or the functional ceramics of the stack, against external chemical or mechanical influences. More constant electrical characteristic values of the multilayer component can be achieved as a result.

In accordance with one embodiment, the passivation of the stack or of the multilayer component is achieved by means of a glass-containing or polymer-containing layer applied on at least one outer surface of the stack. However, the passivation could also be achieved by means of a ceramic-containing layer on the outer surface of the stack. The ceramic-containing layer preferably contains one of the following materials: ZrOₓ, MgO, AlOₓ, where x denotes a number ≧1 and indicates the magnitude of the oxidation number of elements respectively combined with oxygen.

The electrode layers and also ground electrodes of the electric multilayer component preferably contain one or an alloy of the following materials: silver, palladium, nickel, copper. Preferably, the external contacts which are contact-connected to the electrode layers include a material in common with the electrode layers, which material promotes the contact-connection of both to one another.

In accordance with one embodiment, the electric multilayer component has a resistor that is contact-connected to the external contacts of opposite polarities. The resistor can be printed as a resistive track or layer on the surface of the stack. As an alternative, it can be applied on a passivation and/or be covered by means of a passivation.

In accordance with one embodiment of the electric multilayer component, a plurality of stacks of electrode layers are arranged side by side, wherein the electrode layers of different stacks are arranged on common dielectric layers. In this case, the stacks of electrode layers can be arranged side by side in the longitudinal direction or laterally. With this construction, the multilayer component has an array of multilayer structures which can be arranged in the same multilayer component. Since the multilayer component is preferably constructed monolithically, this means that a plurality of multilayer structures can be contained monolithically as an array in a single stack or basic body.

In accordance with one embodiment of the multilayer component, the dielectric layers contain a varistor ceramic. A stack of dielectric layers created in this way forms together with electrode layers a multilayer varistor. The varistor ceramic preferably includes zinc oxide (ZnO).

As an alternative or in addition dielectric layers of the multilayer component can contain a capacitor ceramic from the classes X7R, COG, Z5U. Dielectric layers embodied in this way and arranged side by side alternately with electrode layers can form a multilayer capacitor which could be integrated as a multilayer structure alongside a multilayer varistor in the same electric multilayer component.

The dielectric layers could also contain a nonlinearly resistive material, for example, an NTC material or a PTC material. If a plurality of such dielectric layers are arranged side by side alternately with electrode layers, a multilayer NTC structure or a multilayer PTC structure can respectively be created, wherein the multilayer structures could be integrated with the other multilayer structures already mentioned in the same multilayer component.

The above multilayer structures which are integrated in a common stack of dielectric layers and the dielectric layers of which contain a varistor ceramic, capacitor ceramic or an NTC material or PTC material can form electric multilayer components having an, if appropriate, multiplicity of electrical functions, in particular of electrical filter functions. Nevertheless, these can have advantageously small structural sizes or be produced in a flat design.

### BRIEF DESCRIPTION OF THE DRAWINGS

The subject matters described will be explained in greater detail on the basis of the following figures and exemplary embodiments. In this case:

FIG. 1A shows a lateral cross-sectional view of an electric multilayer component;

FIG. 1B shows a plan view of a cross section of the component shown in FIG. 1A, wherein the cross section runs between the external contacts and the stack of the multilayer component;

FIG. 1C shows a plan view of a cross section of the component shown in FIG. 1A, wherein the cross section runs through the external contacts of the multilayer component;

FIG. 2A shows a lateral cross-sectional view of the component in accordance with FIG. 1A with an additional passivation layer;

FIG. 2B shows a plan view of a cross section of the component shown in FIG. 2A, wherein the cross section runs between the upper passivation layer and the stack;

FIG. 2C shows a plan view of a cross section of the component shown in FIG. 2A, wherein the cross section runs between the external contacts and the upper passivation layer;

FIG. 2D shows a plan view of a cross section of the component shown in FIG. 3A, wherein the cross section runs through the external contacts of the multilayer component;

FIG. 3A shows a lateral cross-sectional view of the component in accordance with FIG. 2A with enlarged electrode layer surfaces;

FIG. 3B shows a plan view of a cross section of the component shown in FIG. 3A, wherein the cross section runs between the upper passivation layer and the stack of dielectric layers;

FIG. 3C shows a plan view of a cross section of the component shown in FIG. 3A, wherein the cross section runs between the external contacts and the upper passivation layer;

FIG. 3D shows a plan view of a cross section of the component shown in FIG. 3A, wherein the cross section runs through the external contacts of the multilayer component;

FIG. 4A shows a lateral cross-sectional view of an electric multilayer component comprising electrode layers which do not mutually overlap one another in orthogonal projection;

FIG. 4B shows a plan view of a cross section of the component shown in FIG. 4A, wherein the cross section runs between the upper passivation layer and the stack of dielectric layers;

FIG. 4C shows a plan view of a cross section of the component shown in FIG. 4A, wherein the cross section runs through the external contacts of the multilayer component;

FIG. 5A shows a lateral cross-sectional view of an electric multilayer component comprising a plurality of multilayer structures;

FIG. 5B shows a plan view of a cross section of the component shown in FIG. 5A, wherein the cross section runs between the external contacts and the stack of dielectric layers;

FIG. 5C shows a plan view of a cross section of the component shown in FIG. 5A, wherein the cross section runs through the external contacts;

FIG. 6A shows a lateral cross-sectional view of an electric multilayer component comprising a plurality of multilayer structures with additional ground electrodes and a ground contact;

FIG. 6B shows a plan view of a cross section of the component shown in FIG. 6A, wherein the cross section runs between the external contacts and the stack of dielectric layers;

FIG. 6C shows a plan view of a cross section of the component shown in FIG. 6A, wherein the cross section runs through the external contacts and the ground contact,

FIG. 7 shows the lateral cross-sectional view of a mounting arrangement for an electric multilayer component of flip-chip design which is mounted on a printed circuit board;

FIG. 8 shows a lateral cross-sectional view of a mounting arrangement for an electric multilayer component of flip-clip design which is arranged within a laminate or within a layer sequence of a printed circuit board;

FIG. 9 shows a lateral cross-sectional view of a surface-mountable electric multilayer component with ground electrodes and electrode layers running on end and with a resistor;

FIG. 10 shows a plan view of that side of the multilayer component in accordance with FIG. 9 which has the resistor;

FIG. 11 shows a plan view of that side of the multilayer component in accordance with FIG. 10 which has the ground contact.

The following list of reference symbols can be used in conjunction with the drawings:
1 Stack of dielectric layers and electrode layers
2 Dielectric layers
3 Electrode layers
3a Shorter limbs of an L-shaped electrode layer
3b Longer limbs of an L-shaped electrode layer
4a First external contact
4b Second external contact
4c Ground contact
5a Outer surface of the multilayer component on the contact side
5b Other outer surface of the multilayer component
7 Ground electrode
8 Passivation layer
9 Printed circuit board
10 Substrate layers of a printed circuit board
11 Electrical conductor track of a printed circuit board
12 Plated-through hole of a printed circuit board
13 Solder bump or solder ball
14 Resistor

### DETAILED DESCRIPTION OF ILLUSTRATIVE EMBODIMENTS

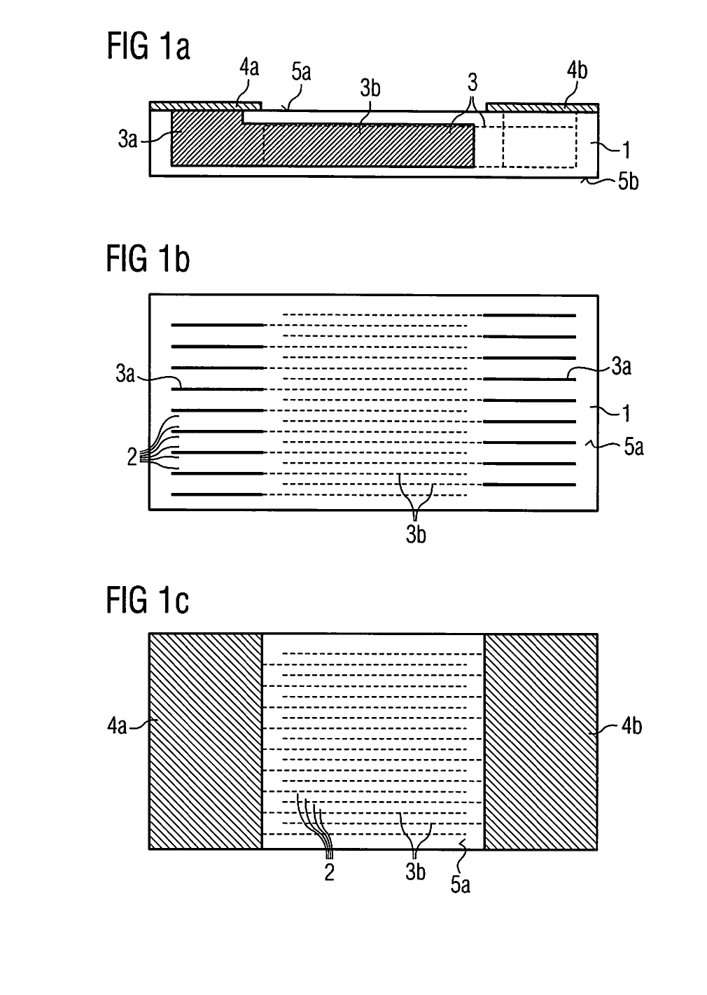

The illustration in accordance with FIG. 1A is a lateral cross-sectional view of an electric multilayer component having a stack 1 of dielectric layers 2 (shown in FIG. 1B) and electrode layers 3 arranged side by side laterally relative to a mounting surface. Arranged on the contact side 5a of the stack 1 are external contacts 4a and 4b, which, in a manner offset from the center of the stack 1, are situated in each case in an edge region of the contact side 5a of the stack. Electrode layers 3 are connected by a respective contact-connection end in each case to an external contact and extend in L-shaped fashion into the interior of the layer stack 1, wherein the longer limb 3b of each L-shaped electrode layer 3, in orthogonal projection, overlaps the longer limb 3b of an adjacent L-shaped electrode layer 3.

FIG. 1B shows the cross sections or edges at the contact side of the shorter limbs 3a of the electrode layers 3 as continuous lines and longer limbs 3b, situated further in the interior of the layer stack, of the electrode layers 3 as dashed lines. The cross-sectional area in accordance with this illustration is situated between the external contacts 4a and 4b shown by FIG. 1A and the extension region of the longer limbs 3b of the L-shaped electrode layers 3. Moreover, the upper edges of the dielectric layers 2 are shown in this cross-sectional view.

FIG. 1C is an illustration of a cross-sectional plane which runs in planar fashion through the external contacts 4a and 4b. The cross sections of the shorter limbs 3a of the electrode layers 3 are covered by the surfaces of the external contacts 4a and 4b in this view, wherein the cross sections of the longer limbs 3b of the electrode layers 3 are illustrated by dashed lines.

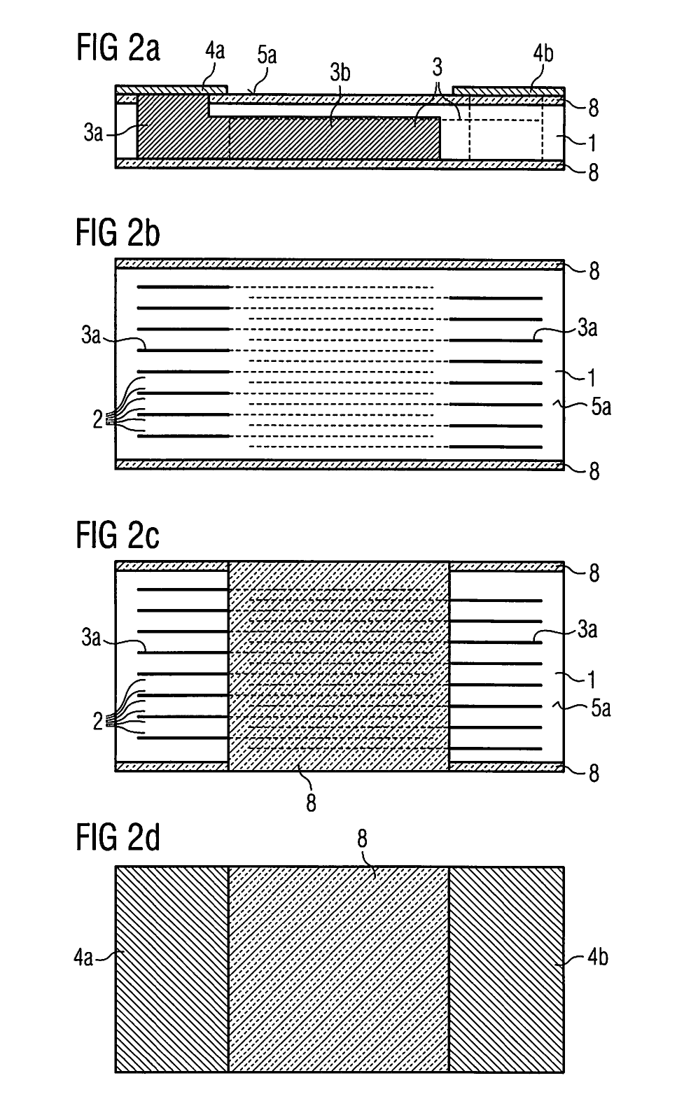

In contrast to FIG. 1A, FIG. 2A shows an electric multilayer component having a stack 1 of dielectric layers 2 (shown in FIG. 2B) and electrode layers 3 arranged side by side, wherein the stack 1 is provided with a passivation layer 8 in each case on the top and bottom sides. In this case, a bottom side of the multilayer component refers to the side which will later face the mounting surface.

Further passivation layers are applied at the lateral outer surfaces of the layer stack 1 but the further passivation layers are not visible in this cross-sectional view in order that the inner structure of the multilayer component can be made visible from the side.

The passivation layers 8 shown form a top layer and a bottom layer, respectively, of the multilayer component. In accordance with this embodiment, the shorter limbs 3a of the L-shaped electrode layers 3 are led through the passivation layer 8 forming a bottom layer as far as the surface 5a thereof and are directly connected to the external contacts 4a and 4b arranged on the passivation layer 8.

FIG. 2B shows a plan view of a cross section in the bottom region of the multilayer component shown by FIG. 2A, wherein ends of the shorter limbs 3a of the electrode layers 3 that are led out to the surface 5a of the passivation layer 8 forming a bottom layer are shown by means of continuous lines and longer limbs 3b, situated deeper in the interior of the stack 1, of the electrode layers 3 are shown by means of dashed lines. Passivation layers 8 which laterally delimit the layer stack 1 are also shown.

FIG. 2C is a further plan view of a cross section in the bottom region of the multilayer component shown by FIG. 2A, wherein the cross section runs through the passivation layer 8 serving as a bottom layer. However, for the purpose of the illustration, only the central region of the passivation layer 8 relative to the lateral extent of the multilayer component is shown in order that the ends of the shorter limbs 3a of the respective electrode layers 3 that are led as far as the outer surface 5a of the multilayer component on the bottom side become visible. Moreover, further passivation layers 8 applied laterally to the layer stack are shown as the bottom edges of the further passivation layers shown by this figure.

FIG. 2D is an illustration of a cross section running through the external contacts 4a and 4b shown by FIG. 2A wherein the rectangular surfaces of the external contacts and also the rectangular surface of that region of the passivation layer 8 which is arranged between the external contacts are shown. The external contacts 4a and 4b and also the passivation layer 8 on the contact side together cover the contact side of the multilayer component preferably completely.

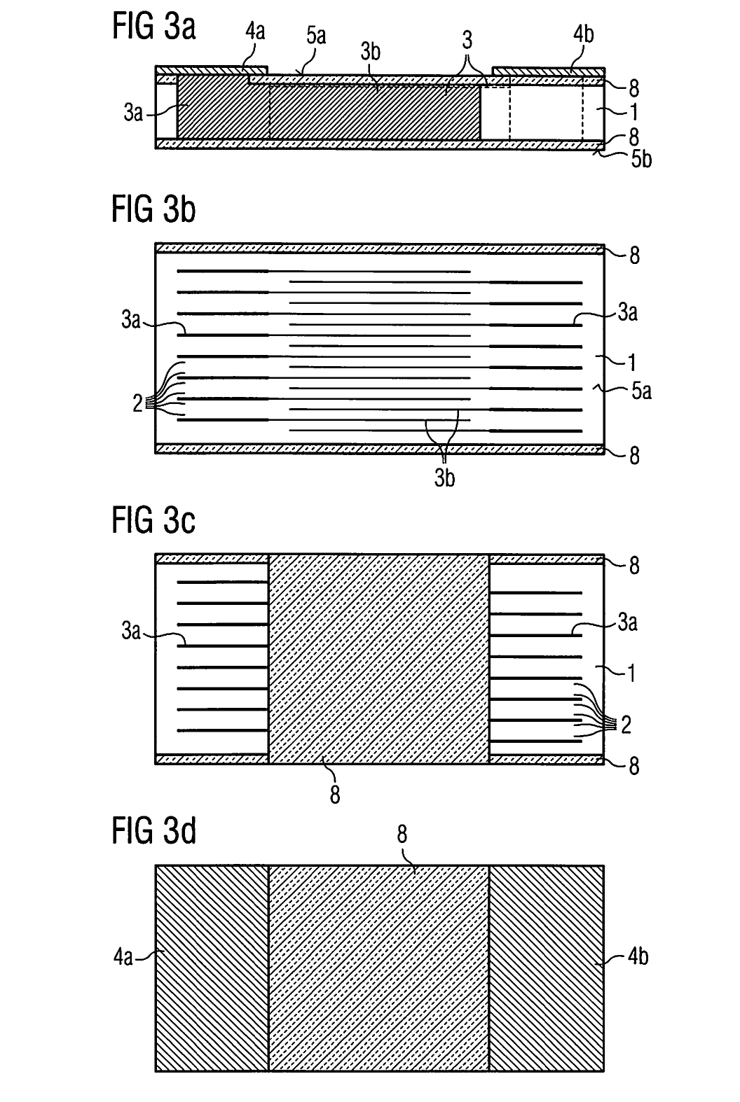

In contrast to FIG. 2A, FIG. 3A shows electrode layers 3 having enlarged surfaces overall, wherein, in particular, the vertical extents of the longer limbs 3b of the electrode layers 3 have been enlarged, such that the top edges (in the lower region of the multilayer component in the figure) of the limbs 3b are led as far as an upper passivation layer or bottom layer 8.

FIG. 3B is a plan view of a cross section of the multilayer component shown by FIG. 3A, wherein the cross section runs through the electrode layers 3 and, consequently, the plan view of the shorter limbs 3a of the electrode layers 3 is shown as thicker, continuous, horizontal lines and the plan view of the longer limbs 3b of the electrode layers 3 is shown by a thinner, continuous, horizontal line. Moreover, passivation layers 8 applied laterally to the layer stack 1 are shown.

In contrast to FIG. 3B, FIG. 3C shows a plan view of a cross section of the multilayer components shown by FIG. 3A wherein the cross section runs at the boundary between the bottom layer or passivation layer 8 on the contact side and the external contacts 4a and 4b arranged on the bottom layer. Consequently, the ends of the shorter limbs 3a of the electrode layers 3 that are led as far as the outer surface 5a of the bottom layer are visible in this plan view. The latter are shown by continuous horizontal lines. Moreover, passivation layers 8 applied laterally to the layer stack 1 or the upper edges of the passivation layers are shown.

FIG. 3D is a plan view of a cross section of the multilayer component shown by FIG. 3A, wherein the cross section runs through the external contacts 4a and 4b arranged on the bottom layer on the contact side and that region of the passivation layer 8 which is present between said external contacts is visible.

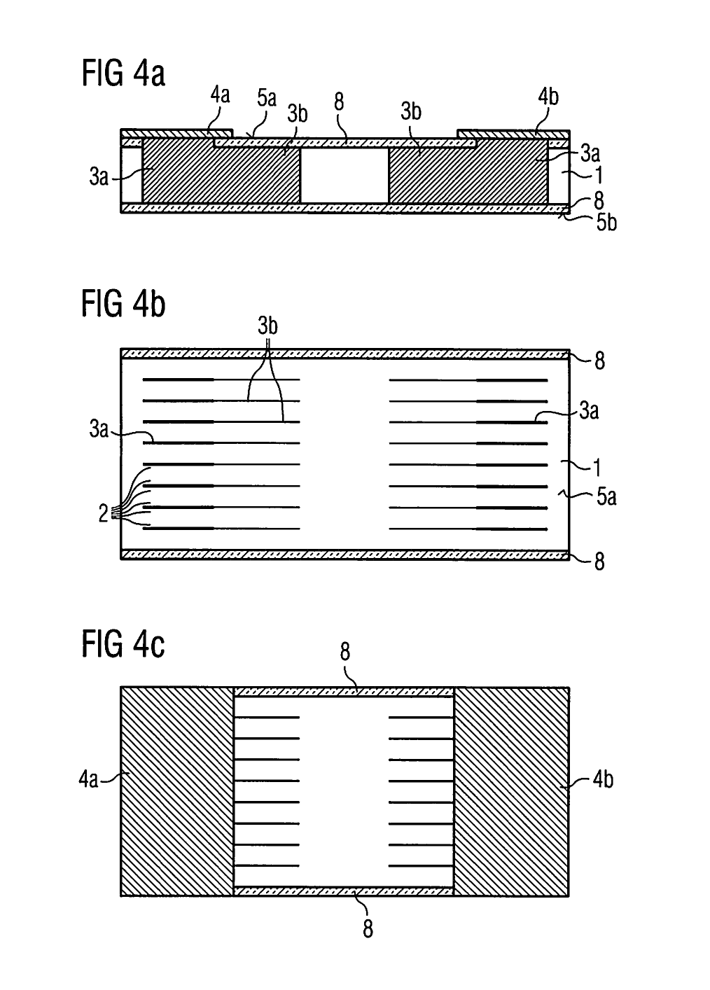

FIG. 4A shows a lateral cross-sectional view of an electric multilayer component having a layer stack 1 of dielectric layers 2 (shown in FIG. 4B) and electrode layers 3, wherein the electrode layers have smaller or shorter L shapes in comparison with the previous exemplary embodiments. In this case, the L-shaped electrode layers 3 extend from the external contacts 4a and 4b less deeply into the interior of the layer stack 1 in comparison with the exemplary embodiments already described. In particular, shorter limbs 3a of electrode layers 3 having different polarities do not overlap in orthogonal projection, instead in an electrical interaction between electrode layers having different polarities takes place in a plane of the layer stack 1 that runs parallel to a mounting surface. In particular, two electrode layers having different polarities are arranged on a common dielectric layer 2, wherein a capacitance is produced between the mutually facing ends of the longer limbs 3b of the electrode layers 3 in the same plane on the common dielectric layer 2. This embodiment makes it possible to produce comparatively low capacitances which are used in some electronic applications. In this embodiment, too, preferably upper and lower passivation layers 8 or a passivating bottom layer 8 and a passivating top layer 8 are present, which delimit the layer stack 1 on the underside and top side respectively. External contacts 4a and 4b are arranged on the upper top layer 8, wherein the shorter limbs 3a of the electrode layers are led through the passivation layer on the contact side and directly connected to the respective external contacts 4a and 4b.

FIG. 4B is a plan view of a cross section of the multilayer component shown by FIG. 4A, wherein the cross section is arranged between the passivation layer 8 on the contact side 5a and the layer stack 1 in accordance with FIG. 4A. Consequently, the cross sections or edges of the shorter limbs 3a of the electrode layers are shown by thicker, horizontal lines and the edges of the longer limbs 3b of the electrode layers 3 are shown by thinner, horizontal lines. Moreover, passivation layers 8 applied laterally to the layer stack 1 are shown.

FIG. 4C is a plan view of a cross section of the multilayer component shown by FIG. 4A, wherein the cross section runs through the plane of the external contacts 4a and 4b arranged on the passivation layer 8 on the contact side. Parts of the upper edges of the longer limbs 3b of the electrode layers 3 are shown, which are situated below the rectangular external contacts 4a and 4b in part in this projection. For the purpose of the illustration, the passivation layer A present in principle between the external contacts 4a and 4b and the layer stack 1 is not illustrated, in order that the inner regions of the electrode layers 3 become visible.

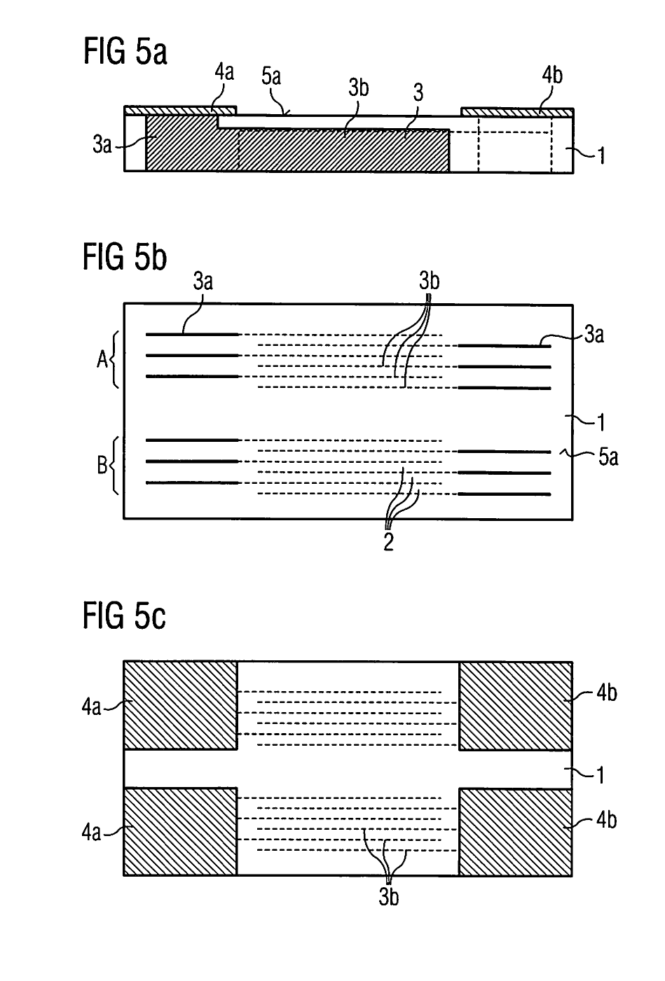

FIG. 5A shows an electric multilayer component as an array of multilayer structures, wherein a lateral cross-sectional view of this multilayer component shows electrode layers 3 beginning at the external contacts 4a and 4b and being continued in L-shaped fashion into the interior of the stack 1.

FIG. 5B shows a cross section of the multilayer component shown by FIG. 5A in the plane between the external contacts 4a, 4b and the layer stack 1. By means of this plan view, a plurality of multilayer structures A and B or the bottom edges thereof are visible, wherein each multilayer structure includes a layer sequence of dielectric layers 2 and electrode layers 3 arranged side by side. A multilayer structure has a specific electrical function such as, for example, a multilayer capacitor, a multilayer varistor, multilayer PTC thermistor or multilayer NTC thermistor. The multilayer structures A and B can be monolithically integrated in a multilayer component. Electrical decoupling layers can be present between multilayer structures having different electrical functions, the decoupling layers avoiding electromagnetic cross talk between the multilayer structures. In accordance with this figure, the contact-side edges of the shorter limbs 3a of the L-shaped electrode layers and also the contact-side edges of the longer limbs 3b of the L-shaped electrode layers are shown for each multilayer structure A, B.

FIG. 5C shows a cross section of the multilayer component presented by FIG. 5A in a plane which runs through the flip-chip external contacts 4a and 4b. The figure shows how, for each multilayer structure, external contacts are provided which are provided which are connected to those ends of the shorter limbs 3a of the L-shaped electrode layers of respective multilayer structures which are led out toward the contact side. Consequently, the outer surface of a layer stack 1 on the contact side could be provided with a plurality of external contacts arranged in edge regions in each case.

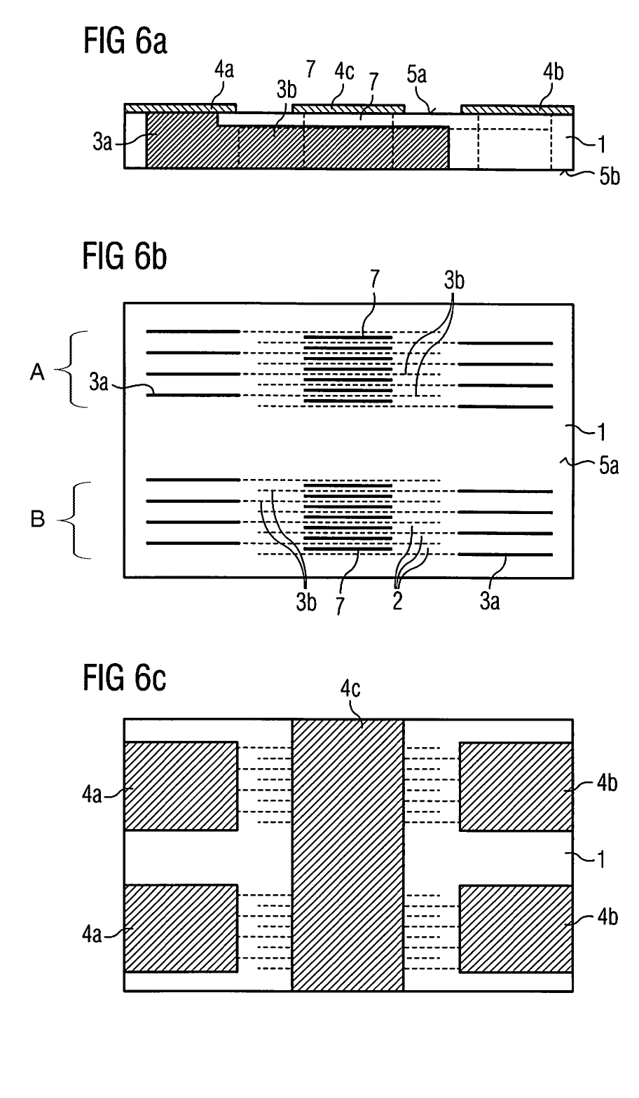

FIG. 6A is a lateral cross-sectional view of an electric multilayer component embodied as an array, wherein in comparison with the multilayer component illustrated by FIGS. 5A to 5C, an additional ground contact 4c is arranged on the outer surface 5a of the layer stack 1 on the contact side and this makes contact with ground electrodes 7 arranged between dielectric layers 2 (shown in FIG. 6B) and electrode layers 3. The ground contact 4c is preferably arranged on the same upper outer surface 5a of the layer stack 1 as the external contacts 4a and 4b that make contact with the electrode layers 3. Consequently, a flip-chip contact-connectable electric multilayer component which can be used as a filter is offered, which has at a single side surface, all the electrical external contacts which can be contact-connected to corresponding counter-contacts of a printed circuit board.

FIG. 6B illustrates a cross section of the multilayer component shown by FIG. 6A, wherein this cross section is arranged between the external contacts 4a, 4b, 4c arranged on the outer surface 5a on the contact side and the layer stack 1. This cross-sectional view shows the contact-side edges of the ground electrodes 7, which reach as far as the outer surface 5a of the layer stack 1 on the contact side in order to enable a contact-connection to a ground contact 4c arranged on the outer surface. Furthermore, a plurality of multilayer structures A and B are shown, which could have different electrical functions, such as, for example, as a multilayer capacitor or a multilayer varistor. The ground electrodes 7 together with the ground contacts 4c are able to dissipate high-frequency interference signals or high-frequency frequencies originating from an overvoltage, in order thus to impart a favorable filter behavior to the multilayer component and to protect it against such overvoltages.

FIG. 6C shows a cross section of the multilayer component shown by FIG. 6A in a lateral view, wherein the cross section runs through the external contacts 4a and 4b for the respective multilayer structures A and B, the external contacts being arranged on the contact side at the outer surface 5a of the layer stack 1. In this case, the areal, rectangular extent of the ground contact 7 and also the areal extents of the external contacts 4a, 4b that make contact with the electrode layers of the multilayer structures A and B are shown. Below the ground contact, the bottom edges of the longer limbs 3b of the electrode layers 3 are shown by means of dashed lines.

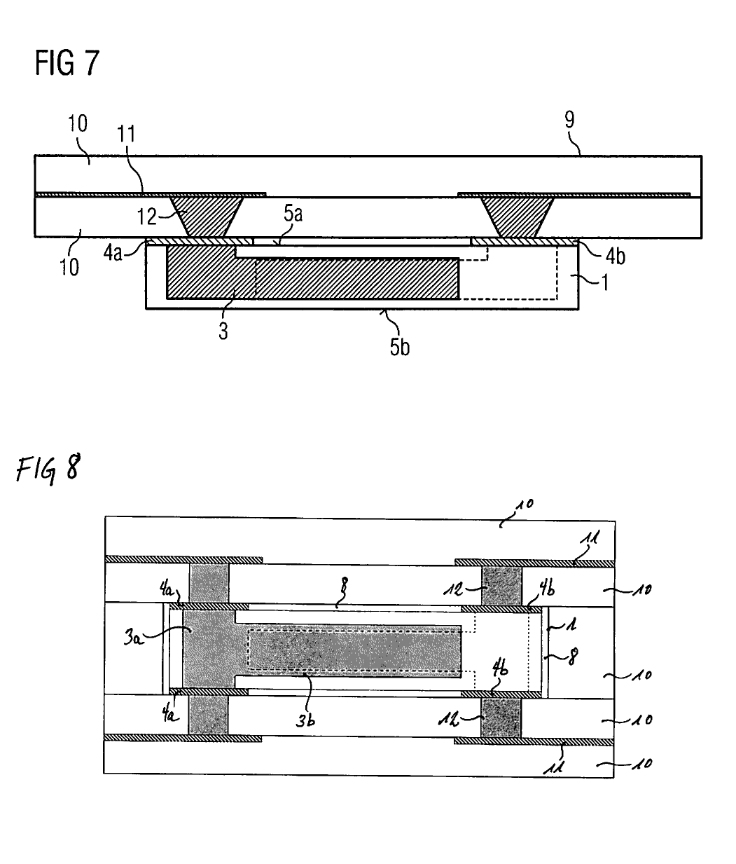

FIG. 7 shows an electric multilayer component having a construction described in this document, which component is mounted by means of flip-chip contacts 4a and 4b on a printed circuit board 9, wherein the flip-chip contacts 4a and 4b are contact-connected in particular to plated-through holes or vias 12 filled with an electrically conductive material, for example, copper. The vias 12 can be contact-connected to conductor tracks 11 integrated in the printed circuit board. The printed circuit board preferably has a plurality of layers 10 to which conductor tracks and further electronic structures can respectively be applied. The layers of the printed circuit board are preferably electrically insulating and preferably contain a polymer.

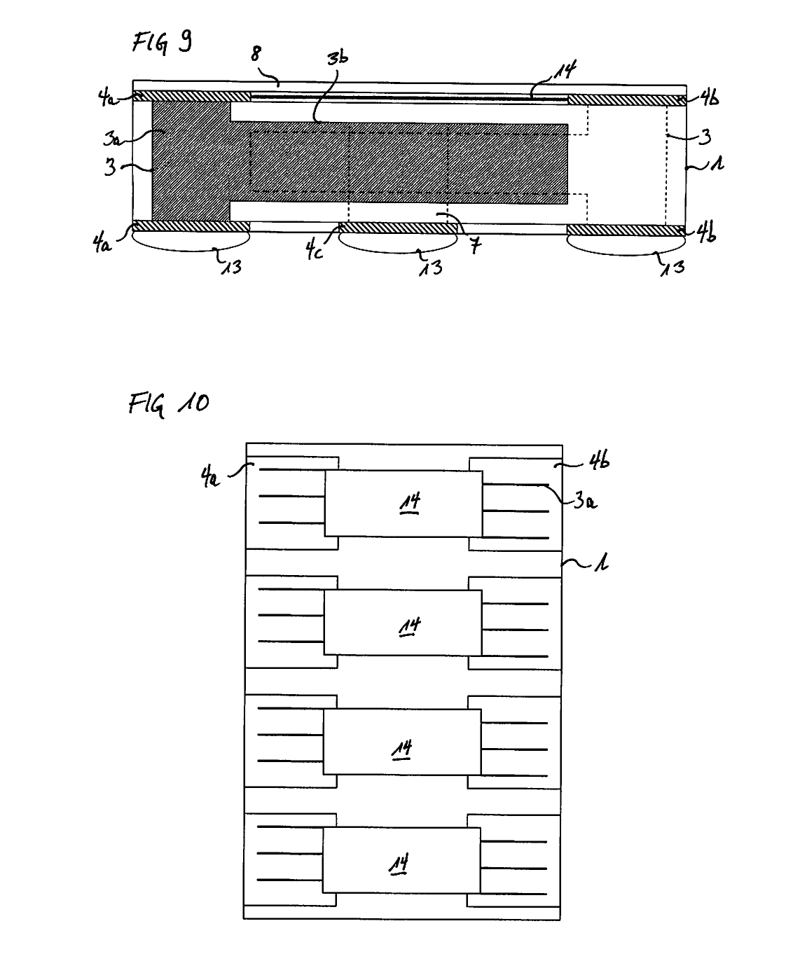

FIG. 8 shows an arrangement including a printed circuit board laminate containing a multilayer component having vertically oriented internal electrodes in accordance with exemplary embodiments described above. The internal electrodes run on end with respect to the printed circuit board layers 10 of the laminate. The printed circuit board laminate involves printed circuit board layers 10 which are stacked one above another and to which electrically conductive or electrically insulating structures can be applied.

The stack 1 of dielectric layers and electrode layers is applied on an end of a printed circuit board layer 10. The top side and the underside of the stack 1 is in each case provided with external contacts 4a and 4b. In this case, external contacts 4a and 4b on the underside make contact with plated-through holes 12 incorporated in the printed circuit board layer 10 on which the stack 1 is arranged. The plated-through holes 12 are in each case contact-connected to a conductor track 11, which are applied on a further printed circuit board layer 10 of the laminate. On the top side, the stack 1 of the multilayer component is electrically contact-connected in an analogous manner.

By comparison with exemplary embodiments described above, the electrode layers 3 of the stack 1 have the shape of a T, wherein the shorter limb 3a of the T-shaped internal electrode is connected, in a manner running vertically, to external contacts 4a of the same polarity which are applied on the top side and underside on the stack. In this case, the longer limb 3b of the T-shaped internal electrode runs perpendicularly to the shorter limb of the internal electrode and it is electrically insulated from counter-contacts.

In order to produce the arrangement, the multilayer component is mounted onto a printed circuit board layer 10. In this case, the stack 1 with its external contacts on the underside is placed in a targeted manner onto the plated-through holes 12 of the printed circuit board layer in order thus to produce an electrical contact-connection on the underside. A further printed circuit board layer is placed onto the multilayer component mounted in this way, the further printed circuit board layer including a deformable material such as, for example, resin or soft polymer on the underside, that is to say on the side facing the multilayer component. This printed circuit board layer is preferably applied by means of a vacuum lamination method. The production of free spaces between the multilayer component and surrounding material of the applied printed circuit board layer is avoided in this case. This can be achieved, for example, by means of a suitable temperature and pressure setting during the application of the printed circuit board layer. For the plated-through holes 12 of the printed circuit board layer lying on the multilayer component cutouts are produced, for example, by means of milling, preferably by means of a laser, the cutouts being filled with an electrically conductive material, such as copper, for example. A UV/CO₂ dual laser beam is preferably used for producing the cutout. On the top side of the printed circuit board layer now provided with plated-through holes, preferably copper-containing conductor tracks 11 can subsequently be printed on, which are connected to the plated-through holes 12. A further printed circuit board layer 10 can cover the printed circuit board layer previously placed onto the multilayer component.

Instead of a printed circuit board layer being placed onto the multilayer component, it is possible, as an alternative to produce a cutout in a printed circuit board layer, into which the multilayer component is inserted with a tight fit. Preferably the top side of the multilayer component in this case runs in plane fashion with respect to the top side of the printed circuit board layer in which the multilayer component is embedded. The depth of the cutout or of the hole in the printed circuit board layer thus preferably corresponds to the height of the multilayer component put on end. The cutout is preferably produced by means of milling, in particular, laser milling.

In accordance with one embodiment of the arrangement, a surface-mountable component (SMD chip) with external contacts on the underside, for example, in the form of solder bumps or solder balls is mounted onto the printed circuit board laminate or the plated-through holes thereof or the conductor tracks thereof connected to plated-through holes. An arrangement of electric components and printed circuit board structures with high integration density in a flat design is thus achieved.

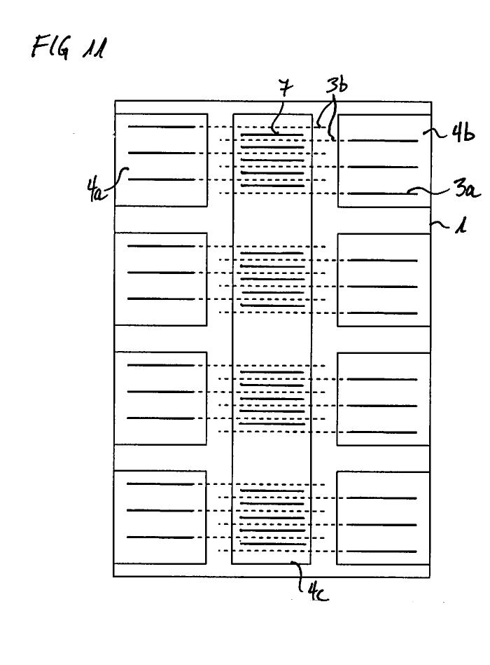

FIG. 9 shows a surface-mountable electric multilayer component having electrode layers 3 running perpendicularly relative to a mounting surface or printed circuit board layer (not shown) to be connected via solder bumps 13. An additional external contact 4c forms an electrical external contact for a ground electrode 7 arranged in the stack. Between the external contacts 4a and 4b on the top side and connected to the external contacts, a resistor 14 runs at the surface of the stack, that is to say, for example, along the edges of the dielectric layers associated therewith. The resistor 14 can be printed on as a resistive track or layer and preferably contain ruthenium oxide (RuOₓ), where x denotes a number ≧1 and indicates the magnitude of the oxidation number. A passivation layer 8 can optionally be present between the resistor 14 and the surface of the stack 1. This figure shows a passivation layer 8 covering the resistor 14. A Π filter is produced with the resistor, wherein capacitances are formed between electrode layers 3 of opposite polarities and dielectric layers lying therebetween and these are connected up to one another by means of a resistor and a ground. Although a Π filter is mentioned here by way of example, other filters having this surface-mountable design and internal electrodes running perpendicularly to a mounting surface can also be provided, such as a low-pass or noise filter, for example. The multilayer component can be embodied as a filter array or as a filter module having a plurality of sets of internal electrodes and external contacts assigned thereto. In this case, however, respective filters or sets of internal electrodes share the same or a common stack of dielectric layers.

FIG. 10 shows a plan view of the top side of a filter array or multilayer component module in accordance with FIG. 9. It shows how resistors 14 in each make contact with the external contacts 4a and 4b of a filter. The edges of the shorter limbs 3a which are connected to the external contacts 4a and 4b are shown by horizontal lines.

FIG. 11 shows a plan view of the underside of a filter array or multilayer component module in accordance with FIG. 9. It shows how the ground electrodes 7 of each filter make contact with a ground contact 4c. In this case, the ground contact 4c is preferably embodied as an elongate strip at the underside of the stack 1. The dashed lines show the edges of the longer limbs 3b of the internal electrodes 3, the longer limbs being embedded in the multilayer component.

What is claimed is:

1. An electric multilayer component, comprising:
a stack of dielectric layers and electrode layers arranged side by side, and
a first external contact and a second external contact arranged at a mounting surface of the stack, the external contacts being flip-chip contact-connectable, the first and second external contacts of opposite polarities;
wherein the electrode layers comprise a first group of electrode layers and a second group of electrode layers, one end of each electrode layer in the first group being connected to the first external contact and one end of each electrode layer in the second group being connected to the second external contact.

2. The electric multilayer component as claimed in claim 1, wherein a stacking direction of the stack runs substantially parallel to a mounting surface onto which the multilayer component is mountable.

3. The electric multilayer component as claimed in claim 1, wherein the electrode layers at least partly overlap in orthogonal projection.

4. The electric multilayer component as claimed in claim 1, wherein the electrode layers do not overlap in orthogonal projection, are arranged on a common dielectric layer and at a distance from one another.

5. The electric multilayer component as claimed in claim 1, wherein the electrode layers are shaped in such a way that they are connected to a respective external contact at one end in each case and run in direction-changing fashion into an interior of the stack.

6. The electric multilayer component as claimed in claim 1, wherein the electrode layers are L-shaped, wherein a first limb of each electrode layer is connected to an external contact and a second limb of each electrode layer runs parallel to the mounting surface.

7. The electric multilayer component as claimed in claim 6, wherein the second limbs of the electrode layers in different groups of electrodes at least partly overlap in orthogonal projection.

8. The electric multilayer component as claimed in claim 6, wherein the end of a second limb of one electrode layer faces the end of a second limb of an electrode layer of opposite polarity, the second limb being arranged on the same dielectric layer, the ends being at a distance from one another.

9. The electric multilayer component as claimed in claim 1, wherein each electrode layer is led as far as an outer surface of the stack.

10. The electric multilayer component as claimed in claim 1, further comprising a ground electrode arranged on one of the dielectric layers of the stack and being contact-connected at one end to a ground contact arranged at the mounting surface.

11. The electric multilayer component as claimed in claim 1, wherein the first and second external contacts are arranged at a substantially maximum distance from one another on the mounting surface of the stack.

12. The electric multilayer component as claimed in claim 1, wherein the first and second external contacts are arranged at different edge regions of the mounting surface of the stack.

13. The electric multilayer component as claimed in claim 1, wherein at least one outer surface of the stack is at least partly passivated.

14. The electric multilayer component as claimed in claim 13, further comprising a glass-containing layer, wherein the at least one outer surface of the stack is at least partly passivated by means of the glass-containing layer.

15. The electric multilayer component as claimed in claim 13, further comprising a ceramic containing passivation layer, wherein the at least one outer surface of the stack is at least partly passivated by means of the ceramic-containing passivation layer.

16. The electric multilayer component as claimed in claim 15, wherein the ceramic-containing passivation layer comprises at least one material selected from the group consisting of ZrOₓ, MgO, and AlOₓ, where x denotes a number ≧1.

17. The electric multilayer component as claimed in claim 1, wherein the electrode layers comprise at least one material selected from the group consisting of Ag, Pd, Ni, and Cu.

18. The electric multilayer component as claimed in claim 1, wherein the stack comprises a plurality of stacks of electrode layers arranged side by side, wherein electrode layers belonging to different stacks are arranged on common dielectric layers.

19. The electric multilayer component as claimed in claim 1, wherein the dielectric layers comprise a varistor ceramic.

20. The electric multilayer component as claimed in claim 1, wherein the dielectric layers comprise a capacitor ceramic.

21. The electric multilayer component as claimed in claim 1, wherein the dielectric layers comprise a non linearly resistive material.

22. The electric multilayer component as claimed in claim 1, wherein the electrode layers interacting with the dielectric layers form at least one of the following: a multilayer varistor, a multilayer capacitor, a multilayer NTC thermistor or a multilayer PTC thermistor.

23. The electric multilayer component as claimed in claim 22, wherein the multilayer component comprises a multilayer varistor and a multilayer capacitor arranged side by side in the stack.

24. The electric multilayer component as claimed in claim 1, further comprising a resistor connected to the first and second external contacts.

25. A device, comprising:
a multilayer component comprising a stack of dielectric layers and electrode layers arranged side by side, and a first external contact and a second external contact arranged at a mounting surface of the stack, the first and second external contacts being flip-chip contact-connectable, the first and second external contacts of opposite polarities, wherein the electrode layers comprise a first group of electrode layers and a second group of electrode layers, one end of each electrode layer in the first group being connected to the first external contact and one end of each electrode layer in the second group being connected to the second external contact;
a printed circuit board, wherein the multilayer component is mounted on the printed circuit board such that an electrical contact between the multilayer component and the printed circuit board is produced between contacts of a printed circuit board and the first and second external contacts.

26. The device as claimed in claim 25, wherein the contacts of the printed circuit board are connected to plated-through holes led through the printed circuit board.

27. The device as claimed in claim 25, wherein the printed circuit board has a plurality of substrate layers and electrical conductor tracks arranged between the substrate layers.

28. The device as claimed in claim 25, wherein the multilayer component is embedded in a layer sequence of printed circuit board layers.
